(19) United States
(12) Patent Application Publication
(10) Pub. No.: US 2026/0309479 A1
(43) Pub. Date: Oct. 8, 2026

(54) Microsystem Comprising a Flexurally Movable Beam and Multiple Stops

(71) Applicant: COMMISSARIAT A L'ÉNERGIE ATOMIQUE ET AUX ENERGIES ALTERNATIVES, Paris (FR)

(72) Inventor: Thierry VERDOT, Grenoble Cedex 09 (FR)

(73) Assignee: COMMISSARIAT A L'ÉNERGIE ATOMIQUE ET AUX ENERGIES ALTERNATIVES, Paris (FR)

(21) Appl. No.: 19/191,495

(22) Filed: Apr. 28, 2025

(30) Foreign Application Priority Data
Apr. 29, 2024 (FR) FR2404487

(51) Int. Cl. G01B 7/30; G01D 5/16; G01N 21/17

(52) U.S. Cl. CPC G01B 7/30; G01D 5/16; G01N 21/1702; G01N 2021/1704

(57) ABSTRACT

Electromechanical microsystem (1), comprising:
a beam (10) extending from a base (13) to an end (14), the beam being configured to oscillate about an equilibrium position;
at least one strain gauge (11, 12) configured to deform when the angle of rotation of the diaphragm (θ) increases;
a first stop extending at a first offset (e₁) from the central axis and configured to be in contact with the diaphragm when the end moves away from the central axis beyond a first displacement (y₁);
a second stop (202) extends at a second offset (e₂) from the central axis, the second stop being configured to come into contact with the beam when the end moves away from the central axis according to a second displacement (y₂), greater than the first displacement (y₁).

### TECHNICAL FIELD

The technical field of the invention relates to a microsystem comprising a beam that undergoes flexion within a plane, the flexural movement being related to a variable of interest, for example a pressure differential, acceleration or a displacement of the end of the beam.

### PRIOR ART

Sensors such as accelerometers, microphones or gyrometers use microsystems comprising a beam, the movement of which is related to a variable of interest to be measured, for example acceleration, pressure or the displacement of one end of the beam, said displacement possibly being generated by a component connected to the end of the beam. The amplitude of movement can be measured by piezoresistive or piezoelectric strain gauges, said gauges making it possible to convert mechanical strain into a usable electrical signal.

Patent EP2410767 describes, for example, a microphone in which the beam forms a diaphragm subjected to a pressure differential, the term diaphragm referring to the element that separates two sections of the acoustic network of said microphone: an upstream section subjected to the pressure fluctuations of an incident sound wave and a downstream section connected to a rear volume in which the acoustic pressure fluctuations tend to cancel out in the audible frequency range. Strain gauges, suspended between a fixed substrate and the diaphragm, make it possible to measure the movement of the diaphragm induced by pressure fluctuations from the incident sound wave. The measurement principle relies on a change in the resistivity of the material forming each piezoresistive gauge, as a result of compression or elongation caused by the flexural movement of the diaphragm.

One limitation in the use of strain gauges is their capacity to withstand mechanical stress levels that may become excessive when the diaphragm undergoes a significant movement. To this end, EP2410767 mentions a mechanical stop device designed to limit the flexural movement at the end of the movable diaphragm. In principle, once the diaphragm comes into contact with the stop, the operational limit of the device is reached.

Patent EP3136052 describes a similar device dedicated to measuring the large-amplitude movement of a movable mechanical part. In that application, the beam is used as a rigid element between a base resting on a pivot and its end connected to the movable mechanical part via a flexible element. The movement of the beam under consideration is that of a rigid body rotating about an axis of rotation defined by the pivot. The elongation of piezoresistive gauges is therefore related to the displacement of the end of the slender structure through the ratio between the distance of the gauges to the axis of rotation and the length of the beam. In this device, the flexible link connecting the end of the slender structure to the movable mechanical part plays a decisive role, as it ensures conversion of the large-amplitude movement of the movable part into a smaller-amplitude movement at the end of the slender structure. The reduction ratio adopted is intended to lower the mechanical load on the gauges and must be adapted based on the amplitude of movement of the movable part to be measured and the maximum elongation of the gauges. Except for the element referred to above, nothing is specified in EP3136052 for protecting the gauges in the event of exceptional overload. There is a risk that an impact occurring the direction of movement of the movable mechanical part to be measured could lead to an excessive level of stress in the strain gauges.

However, a beam is never perfectly rigid. It can therefore continue to deform under the effect of an excessive load and stress the gauges beyond the stress threshold considered excessive, even when it is in contact with a stop device located at the end of the slender structure, as described in patent EP2410767. The invention described below allows for the design of robust electromechanical systems that preserve the integrity of strain gauges while also expanding their operating range.

### DISCLOSURE OF THE INVENTION

A first object of the invention is an electromechanical microsystem comprising:
a beam extending from a base to an end, the beam being configured to be flexurally movable within a flexion plane under the effect of a mechanical load, starting from an equilibrium position, the beam extending along a central axis when it occupies the equilibrium position, the beam being configured to cause the base to rotate about an axis of rotation, under the effect of flexion, by an angle of rotation within the flexion plane, the angle of rotation being defined relative to the central axis;
at least one strain gauge configured to deform when the angle of rotation increases, the strain gauge being configured to generate a detection signal dependent on the angle of rotation;
   wherein the microsystems comprises a first-rank stop and a second-rank stop, each stop being intended to come into contact with the beam, the microsystem being such that:
the first stop is arranged parallel to the central axis between the second-rank stop and the base;
the first-rank stop extends at a first offset from the equilibrium position, the first-rank stop being configured to come into contact with the beam when the end moves away from the equilibrium position beyond a first displacement;
the second-rank stop extends at a second offset, greater than the first offset, from the central axis relative to the equilibrium position, the second-rank stop being configured to be in contact with the beam when the end moves away from the equilibrium position by a second displacement, greater than the first displacement;
in such a manner that:
   when the end moves from the equilibrium position to the first displacement, the angle of rotation increases;
   when the end moves from the first displacement towards the second displacement, the angle of rotation decreases under the effect of deformation of the beam and a support of the beam against the first-rank stop.

The microsystem may comprise multiple n rank stops, where n is an integer greater than or equal to 2, each n rank stop being arranged:
along the central axis, at a distance from the base that increases as the rank of the stop increases;
perpendicular to the central axis, at an offset from the equilibrium position that increases as the rank of the stop increases;
the n rank stop extending at an n-th offset, greater than the (n−1)th offset, from the equilibrium position, the n rank stop being configured to be in contact with the beam when the end moves away from the equilibrium position by an n-th displacement, greater than the (n−1)th displacement.

According to one possibility, the stops of rank greater than or equal to 2 are positioned to come into contact with the beam simultaneously, the stops being positioned according to a deformation profile of the beam.

According to one possibility, the stops of rank greater than or equal to 2 are positioned to come into contact with the beam successively, the stops being positioned according to a deformation profile of the beam.

According to one possibility, a stop of rank greater than or equal to 2 is configured in such a manner that the offset between said stop and the equilibrium position increases as a function of the distance between the stop and the base, in such a manner that the shape of the stop corresponds to a deformation profile of the beam.

According to one possibility, the strain gauge, or each strain gauge, is a piezoresistive or piezoelectric gauge.

According to one possibility:
the beam extends over a length between the base and the end;
the first distance falls between 0.2 and 0.6 times the length.

The microsystem may comprise a processing unit configured to:
receive the detection signal;
estimate the angle of rotation of the beam based on the detection signal.

According to one possibility, the processing unit is configured to calculate a amplitude of flexion of the beam based on the angle of rotation.

According to one possibility:
the beam is coupled to an actuator configured to induce flexion of the beam;
the processing unit is configured to extract a variation of the detection signal in response to the flexion induced by the actuator;
the processing unit may be configured to determine the amplitude of flexion of the beam based on said variation in the detection signal.

The microsystem may comprise a detector for detecting contact between the beam and the first-rank stop. The processing unit may be configured to determine the amplitude of flexion of the beam based on contact between the beam and the first-rank stop.

According to one possibility, the microsystem comprises a chamber, the microsystem being such that the beam forms a diaphragm delimiting the chamber, the beam being configured to undergo flexion in response to a pressure differential on either side of the beam.

According to one possibility, the end of the beam forms a mass, in such a manner that the beam follows a flexural movement in response to a displacement of the mass, in such a manner that the displacement of the mass causes the base to rotate.

The displacements of the beam and the offsets of each stop may be defined relative to the central axis.

A second object of the invention is a measuring device comprising a microsystem according to the first object of the invention, the measuring device being configured to measure an amplitude of flexion of the beam. The device may be an accelerometer, a gyrometer, or a microphone.

The invention will be better understood by reading the description of the exemplary embodiments presented below, in connection with the figures listed below.

### FIGURES

FIG. 1 shows an example of a photoacoustic detection device.

FIG. 2A shows a microsystem intended for photoacoustic detection.

FIG. 2B is a detail of FIG. 2A.

FIG. 2C shows a limitation of the microsystem described in connection with FIG. 2A.

FIG. 2D is a graph showing the stress applied to the strain gauges as a function of a load applied to the beam.

FIGS. 3A and 3B show a first embodiment of a microsystem implementing the invention. The microsystem in this example is intended for photoacoustic detection similar to the microsystem in FIG. 2A. FIG. 3A shows flexion of the beam of the microsystem when it comes to rest against a first-rank stop. FIG. 3B shows flexion of the beam of the microsystem, already bearing against the first-rank stop, when it comes to bear against a second-rank stop.

FIG. 3C shows different flexural states of the beam in the microsystem described in connection with FIG. 3A.

FIG. 3D shows the impact of the flexion of the beam, as described in connection with FIG. 3C, on the angle of rotation of a base connected to the beam.

FIG. 3E is a graph showing stresses applied to the strain gauges as a function of a load applied to the beam, in the case of the first embodiment.

FIG. 3F shows a configuration in which an actuator is configured to induce flexion of the beam.

FIG. 4A shows a second embodiment of the invention comprising two stops.

FIGS. 4B and 4C show a third embodiment of the invention comprising n stops, n being an integer greater than or equal to 4.

FIG. 5 shows another embodiment of the invention.

FIG. 6 shows another embodiment of the invention.

### DETAILED DESCRIPTION OF PARTICULAR EMBODIMENTS

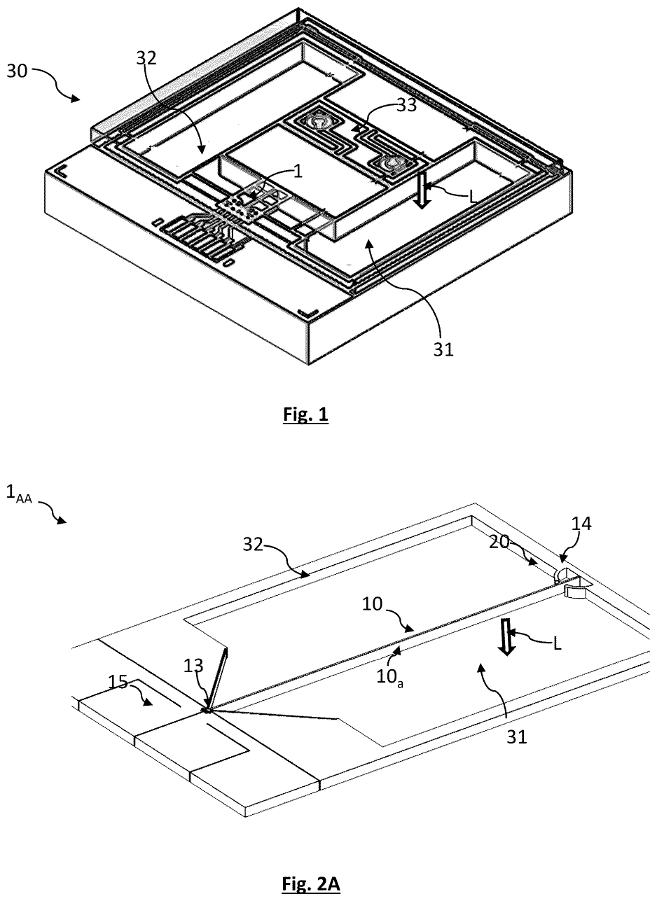

FIG. 1 shows a photoacoustic detection device 30. The device comprises a first and a second chamber 31, 32 intended to be filled with a gas to be analyzed, at the same pressure. The first chamber 31 is configured to be exposed to a laser beam L modulated in amplitude according to a modulation frequency. The laser beam L is emitted at a wavelength corresponding to an absorption wavelength of a gas species potentially present in the gas. Under the effect of the absorption, the illuminated gas heats up, the heating being modulated at the modulation frequency of the laser beam. The modulated heating causes a pressure differential, by photoacoustic effect, in the first chamber 31, said first chamber serving as a measurement chamber. In the second chamber 32, the pressure remains stable, said second chamber serving as a reference chamber.

The pressure differential within the first chamber 31 produces a pressure differential ΔP between the first chamber 31 and the second chamber 32. This pressure differential ΔP is modulated at the modulation frequency of the laser beam.

The device comprises a microsystem 1, described hereafter, of the microphone type, intended to measure the pressure differential ΔP. In addition to the microsystem, the device comprises a microfluidic network 33 enabling the supply of gas to the first chamber 31 and the second chamber 32, as well as the renewal of the gas.

The pressure differential within the first chamber 31 results in a pressure differential ΔP between the first chamber 31 and the second chamber 32, said second chamber being maintained at a constant pressure. The pressure differential ΔP is modulated according to the modulation frequency of the laser beam. The greater the concentration of the target gas species, the greater the pressure differential ΔP.

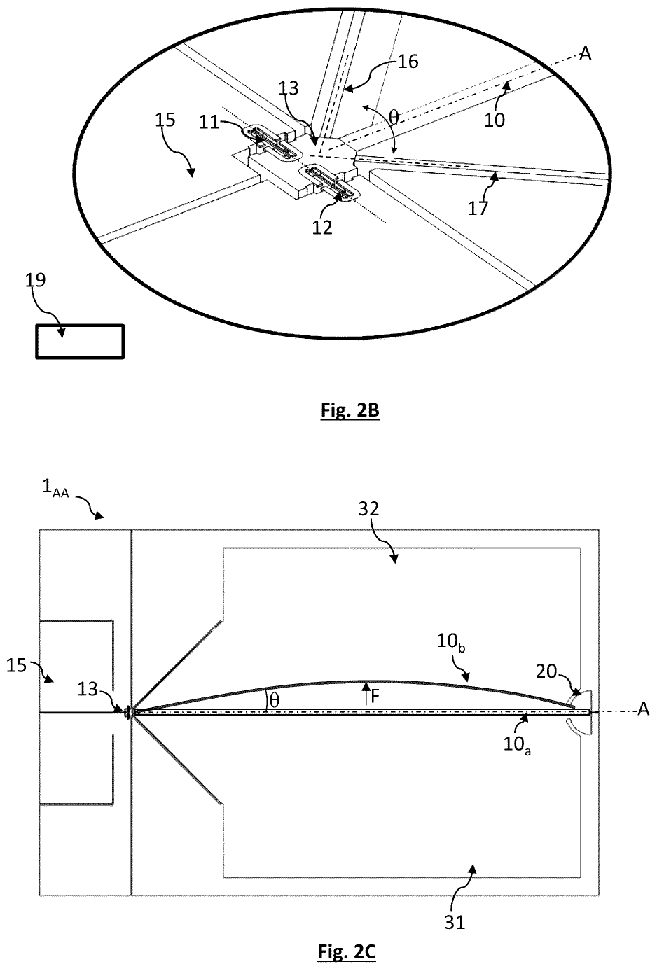

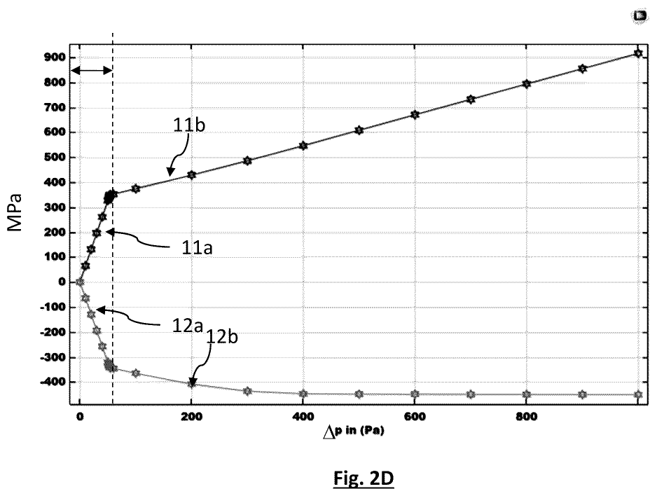

FIGS. 2A and 2B show an example of a prior-art microsystem 1_{AA}. The microsystem comprises a beam 10 forming a diaphragm, the beam being suspended from a base 13 connected to a fixed substrate 15 serving as a support. The beam is flexurally movable within a plane referred to as the flexion plane of the beam. Under the effect of a flexion of the beam, the base 13 is rotatably movable relative to the substrate 15. The base 13 is connected to two arms 16, 17 forming a hinge, allowing the base to rotate about an axis perpendicular to the flexion plane of the beam. The beam 10 separates the first chamber 31 from the second chamber 32. Under the effect of the pressure differential ΔP between the two chambers, the beam is configured to vibrate at an amplitude and a vibration frequency. The beam 10 extends from the base 13 to a end 14. A fixed stop 20 limits the displacement of the end 14 on either side of an equilibrium position 10ₐ. The equilibrium position 10ₐ shown in FIG. 2A and FIG. 2C corresponds to a pressure equilibrium between chamber 31 and chamber 32.

The pressure differential ΔP between chambers 31 and 32, modulated at the modulation frequency of the laser, causes the beam 10 to oscillate at the optical frequency of the laser beam on either side of the equilibrium position 10ₐ. The amplitude of the oscillation depends on the concentration of the target gas species in the illuminated gas.

FIG. 2B shows a detail of the base 13 from which the beam 10 extends. Two strain gauges 11 and 12 are arranged between the base 13 and the fixed substrate 15. As the beam oscillates, the strain gauges are subjected to mechanical stress, either compressive or tensile. The strain gauges allow a detection signal to be generated that depends on their deformation. The detection signal is therefore representative of the amplitude and frequency of the oscillation of the beam in relation to the fixed substrate 15. The detection signal is processed by a processing unit 19, such as an electronic circuit or microprocessor. Two arms 16 and 17 extend from the base and suspend it from the fixed substrate. The arms form a flexible hinge and define a pivot on which the base is supported. The arms prevent translational movement of the base while allowing rotational movement about an axis of rotation perpendicular to a plane in which the beam and the two arms extend. The axis of rotation may be considered to lie at the intersection of two median planes along which the two arms 16 and 17 extend respectively. In FIG. 2B, each median plane is represented by dashed lines.

The oscillation of the beam 10 causes a change in an angle of rotation θ at the base 13. The angle of rotation θ is an angle formed at the base 13 between:
a central axis A, about which the beam 10 extends in the equilibrium position, at which the pressures in the chambers 31 and 32 are equal;
the axis about which the beam 10 extends when deflected by the pressure differential ΔP between the two chambers 31 and 32.

The central axis A is represented by a dash-dotted line. The greater the angle of rotation θ, the greater the stress exerted on the strain gauges 11 and 12.

FIG. 2C shows a view of the microsystem 1_{AA} in the flexion plane pf the beam. In FIG. 2C, the beam 10 is shown in its equilibrium position 10a and in a stop position 10b, in which the beam is bearing against the stop 20. When the beam is in contact with the stop, due to an increase in pressure in the chamber 31, the beam continues to flex while remaining in contact with the stop, which increases the angle of rotation θ measured at the base 13 relative to the equilibrium position. In FIG. 2C, the flexion is indicated by an arrow F. As a result of the flexion, the angle of rotation θ increases, leading to an increase in the deformation stress applied to the strain gauges, which may result in the failure of said strain gauges. Hence, due to the flexibility of the beam, even after it has reached stop 20, the angle of rotation θ may continue to increase due to an increase in the pressure differential ΔP on either side of the beam.

The flexion is shown in an exaggerated manner in FIG. 2C.

In this type of application, the strain gauges are configured to measure very small pressure fluctuations, in the order of 1 Pa. At equilibrium, the pressure in each chamber reaches 1 bar, i.e. 100,000 Pa, for example, which is 100,000 times greater than the differential pressure level intended to be measurable by the strain gauges. Consequently, a pressure imbalance of just a few percent in chambers 31 and 32, for example due to poor design or improper use of the microfluidic circuit 33, may cause a deflection of the beam leading to failure of the strain gauges.

FIG. 2D shows the axial stress in the strain gauges (vertical axis: in MPa) as a function of the pressure differential ΔP on either side of the beam 10 (horizontal axis: in Pa). The curves 11a and 11b correspond to the axial stress in the first strain gauge 11 in tension, respectively:
between the equilibrium position and contact with the stop 20;
after the beam 10 has reached the stop 20, due to the flexion described in connection with FIG. 2C.

Axial stress refers to a stress applied along the axis of each gauge. In the example shown, the gauges 11 and 12 are coaxial, along an axis shown in dashed lines in FIG. 2B.

The curves 12a and 12b correspond to the axial stress occurring in the second strain gauge 12 in compression, respectively:
between the equilibrium position and contact with the stop 20;
after the beam 10 has reached the stop 20, under the effect of flexion.

The stop 20 allows a displacement of the end 14 of beam 10 to be limited. However, it does not allow an increase in the stress applied to the strain gauges after the beam has come into contact with the stop to be avoided. The operating ranges of the strain gauges corresponding to curves 11b and 12b are not usable. Indeed, the stress level may such that it can result in damage to the strain gauges. Therefore, the microsystem 1_{AA} described with reference to the FIGS. 2A to 2D is not optimal. In FIG. 2D, the operating range of the microsystem is marked by a double arrow, said operating range extending from 0 to something in the order of 60 Pa.

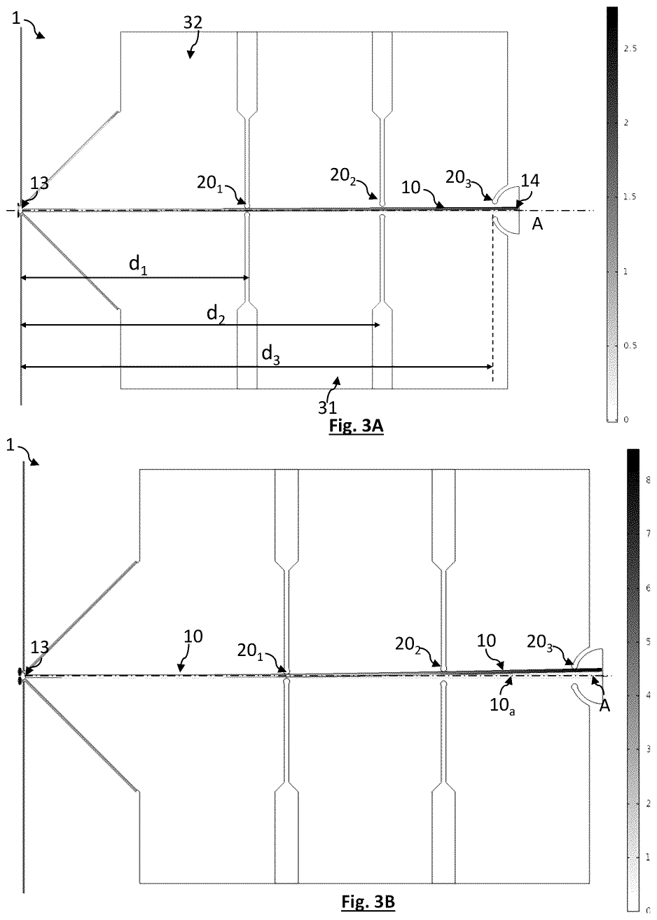

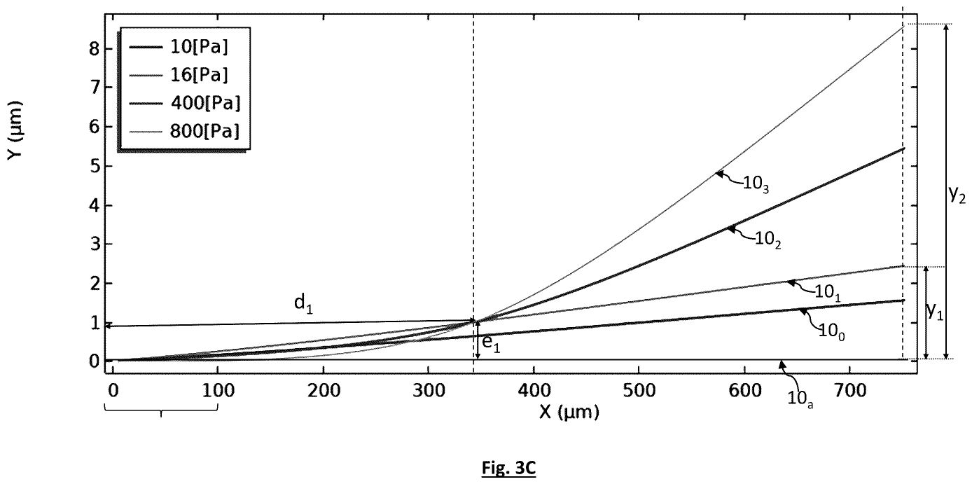

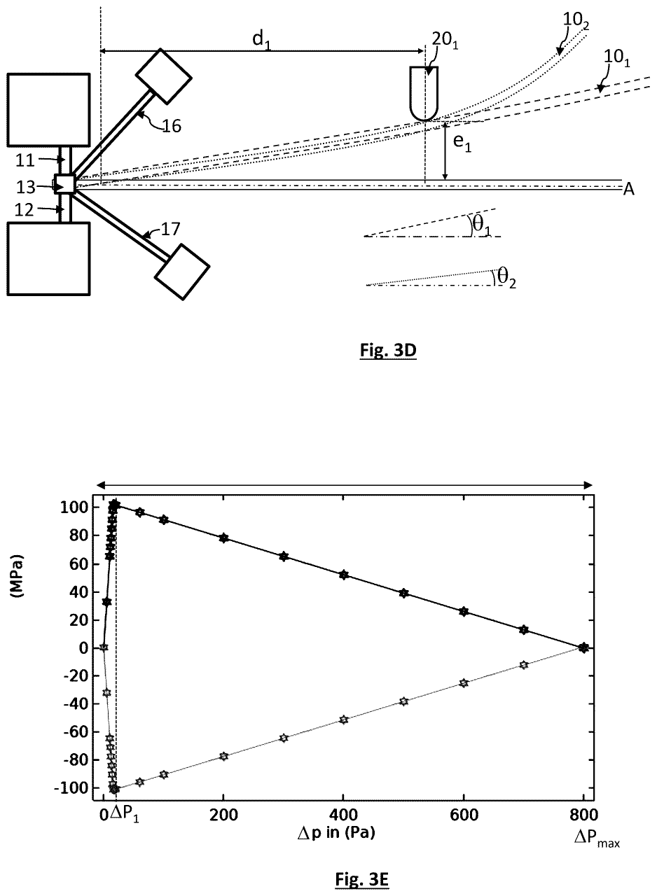

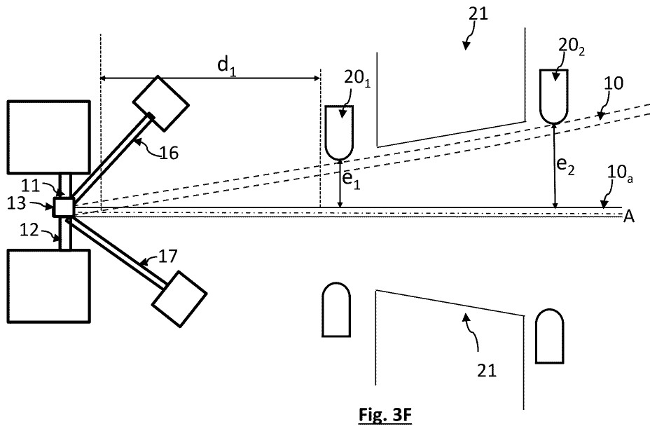

FIG. 3A shows a microsystem 1 according to a first embodiment. The microsystem comprises a first stop 20₁, a second stop 20₂ and a third stop 20₃, all intended to make contact with the beam 10 to limit its rotation. Each stop is assigned a rank n, the rank increasing as the distance dₙ of the stop from the base 13—measured parallel to the central axis from which beam 10 extends—increases. n is a strictly positive integer. The first stop 20₁ is arranged, parallel to the central axis, between the second stop 20₂ and the base 13. The distances d₁, d₂ and d₃ between the first stop 20₁, the second stop 20₂ and the third stop 20₃ and the base 13, respectively, are shown in FIG. 3A.

In a direction perpendicular to the central axis:
the first stop 20₁ extends at a first offset e₁ from the equilibrium position 10ₐ, the first stop being configured to be in contact with the beam 10 when the end 14 deviates from the equilibrium position 10ₐ beyond a first displacement y₁. In this example, displacement refers to a movement of the end 14 of the beam in relation to the equilibrium position 10ₐ.
the second stop 20₂ extends at a second offset e₂, greater than the first offset e₁ from the equilibrium position 10a, the second stop being configured to be in contact with the beam 10 when end 14 deviates from the equilibrium position 10a by a second displacement y₂ which is greater than the first displacement y₁;
the third stop 20₃ extends at a third offset e₃, greater than the second offset e₂, from the central axis A, the third stop being configured to be in contact with the beam 10 when the end 14 deviates from the equilibrium position 10ₐ by a third displacement y₃ greater than or equal to the second displacement y₂.

Hence, in general, and regardless of the embodiment, where n≥2:
each n-th rank stop is positioned at an offset eₙ from the equilibrium position that is greater than or equal to the offset eₙ₋₁ from the lower-ranked stop;
each stop is configured to be in contact with the beam 10 when the end 14 deviates from the equilibrium position 10ₐ by an n^{-th} displacement yₙ greater than or equal to the n−1^{th} displacement yₙ₋₁ from the end 14 at which the beam 10 reaches the n−1^{th} rank stop.

In an equivalent manner, the offset of each stop and each displacement of the end may be defined relative to the central axis A.

The rank n of each stop corresponds to a chronological order in which the beam is progressively supported as it deforms, as the end moves progressively further away from the equilibrium position. A “stop” designates a zone, either a point or extended area, against which the beam is supported for a given displacement of the end 14.

In FIGS. 3A and 3B, the displacement of end 14, perpendicular to the central axis A, is shown using a grayscale scale (unit: μm). FIG. 3A corresponds to a configuration in which the beam 10 is in contact with the first stop 20₁. The displacement y₁ of the end 14 is in the order of 2.5μm. FIG. 3B shows to a configuration in which the beam 10 is in contact with the second and third stops 20₂ and 20₃. The displacement y₂ of the end 14 is in the order of 8.5 μm.

In the embodiment illustrated in FIGS. 3A to 3F, the microsystem comprises a total of N stops, where N=3. The invention applies where N≥2.

When the end 14 moves from the equilibrium position 10ₐ to the first displacement y₁ the angle of rotation Θ increases.

When the end 14 moves from the first displacement y₁ to the second displacement y₂, the beam bears against the first stop 20₁. FIG. 3B illustrates this configuration. If, due to an increase in the pressure differential ΔP, the end 14 moves beyond the displacement y₁, the beam 10 flexes while bearing against the first stop 20₁, as shown in FIGS. 3B and 3C. The deformation leads to a decrease in the angle of rotation θ.

This is an important distinction from the configuration implementing a single stop for each displacement direction, described in connection with FIGS. 2A and 2D. In the configuration shown in FIGS. 3A and 3B, the maximum stress on the strain gauges is observed when the beam 10 reaches the first stop 20₁. If the pressure differential ΔP increases when the beam 10 is bearing against the first stop 20₁, the deflection of the beam between the first stop 20₁ and the end 14 results in a deflection of the beam 10 between the base 13 and the first stop 20₁, said deflection tending to draw the beam closer to the central axis A in the vicinity of the base 13. This effect is detailed in FIGS. 3C and 3D.

FIG. 3C shows four configurations 10₀, 10₁, 10₂ and 10₃ of the beam 10 for four load values, i.e. four pressure differential ΔP values: 10 Pa, 16 Pa, 400 Pa and 800 Pa. The X axis represents a position along the central axis (unit: μm), the base being located at x=0 μm. The Y axis represents the displacement y of the end 14 of the beam. The first stop 20₁ is positioned at an offset e₁ of 1 μm from the equilibrium position 10ₐ and at a distance d₁ of 350 μm from the base 10. The length l of the beam 10 parallel to the central axis A is equal to 750 μm.

When the load ΔP<16 Pa (configuration 10₀), the beam is displaced with a free movement towards the first stop 20₁, said stop being reached when ΔP=16 Pa (configuration 10₁). The value ΔP=16 Pa corresponds to a full-scale pressure value ΔP₁: this is the value of ΔP at which the stress (or mechanical load) applied to the strain gauges 11 and 12 is maximal. The displacement y of the end 14 is approximately 1.5 μm.

When ΔP>16 Pa, the beam bears against the first stop 20₁ and bends in such a manner that the displacement y of the end 14 increases: cf. configurations 10₂ and 10₃. The deformation of the beam causes a deflection towards the central axis A of the portion of the beam adjacent to the base, included between the base (x=0) and a distance of approximately 100 μm from the base. This portion is shown as a bracketed region in FIG. 3C. This results in a decrease in the angle of rotation θ. Hence, when the load, in other words ΔP, applied to the beam exceeds the full-scale load ΔP₁, the portion of the beam adjacent to the base tends to return towards the equilibrium configuration due to the combined effects of the curvature of the beam 10 and the support of said beam against the first stop 20₁. When the load ΔP=ΔPₘₐₓ=800 Pa, the beam reaches the second and third stops 20₂ and 20₃: configuration 10₃. It is then constrained. The value ΔPₘₐₓ=800 Pa corresponds to the maximum load applicable. The displacement of the end 14 reaches a maximum value of 8.5 μm. This is the load at which the portion of the beam adjacent to the base returns towards the central axis as a result of the deflection and reaches an angle of rotation θ of zero, or one that can be considered zero.

FIG. 3D schematically illustrates configurations 10₁ and 10₂, in which the beam reaches and then passes beyond the first stop 20₁, respectively. The maximum angle of rotation, denoted θ₁, is reached in the configuration 10₁. When the load increases from this configuration, the angle of rotation decreases: in configuration 10₂, the angle is θ₂, where θ₂<θ₁. In FIG. 3D, the beam in its equilibrium state is shown as a solid line.

FIG. 3E shows, for the two strain gauges 11 and 12, the stress level (vertical axis, in MPa) as a function of the load applied to the beam (horizontal axis, in Pa). The positive axial stress curve corresponds to strain gauge 11 in extension in FIG. 3D. The negative axial stress curve is observed in the opposite strain gauge (gauge 12 in compression in FIG. 3D). Up to the point of contact with the stop, the load being applied to the gauge 11 increases rapidly, up to a full-scale load ΔP₁ that is equal to 16 Pa in this example. When configuration 10₁ is reached, described in relation to FIGS. 3C and 3D, the stress level applied to the gauges 11 and 12 is maximal. When the load increases and progresses to the maximum load ΔPₘₐₓ the stress level decreases under the effect of the reduction in the angle of rotation. Hence, when ΔP changes between 0 and ΔPₘₐₓ, the maximum stress is applied to the strain gauges when ΔP=ΔP₁.

Such an embodiment presents several advantages:
the maximum stress applied to the strain gauges when the beam reaches the first stop 20₁ (ΔP=ΔP₁), is controlled: this makes it possible to preserve the integrity of the strain gauges;
when the load applied to the beam lies between the full-scale value ΔP₁ and the maximum value ΔPₘₐₓ, the stress exerted on the strain gauges decreases and approaches zero when ΔP=ΔPₘₐₓ. The operating range of the microsystem is thereby improved, said range being represented by a double arrow in FIG. 3E. However, it should be noted that load values ΔP close to the full-scale value ΔP₁ may be difficult to quantify accurately due to the reversal of the angle of rotation on either side of the full-scale value ΔP₁.

The curve shown in FIG. 3E illustrates the fact that the beam can be used in two operating regimes:
a first regime, where 0<ΔP≤ΔP₁, in which an increase in load leads to an increase in the stress applied to the strain gauges;
a second regime, where ΔP₁≤ΔP≤ΔPₘₐₓ, in which an increase in load leads to a decrease in the stress applied to the strain gauges.

The microsystem can only be used across the full dynamic range of measurement if the operating regime is known. To that end, it is possible to couple the beam to an actuator, for example an electrostatic actuator 21 as shown in FIG. 3F. When activated, said actuator induces flexion of the beam, which flexion results in a signal that can be detected by the strain gauges. The operating regime can be identified based on the signal induced by the actuator, with the most direct method of distinguishing between regimes being the sign change in the response when the beam is in contact with the stop. The processing unit 19 can determine the amplitude of flexion of the beam or the load applied to the beam and/or the angle of rotation, depending on the signal detected under the effect of the flexion of the beam induced by the actuator 21.

The electrostatic actuator 21 preferably extends along the beam 10, for example between the first stop 20₁ and the second stop 20₂. The electrostatic actuator 21 is configured to be biased, thereby generating an attractive force. It is arranged so as to avoid any contact with the beam. Placing the electrostatic actuator between two stops helps prevent contact between said actuator and the beam as the beam flexes. Under the effect of the attractive force exerted by the actuator, the beam undergoes flexion in a known direction. Measuring a change in the angle of rotation under the effect of the flexion allows the operating regime to be determined: if the change in the angle of rotation is positive, the beam flexes according to the first operating regime; if the change in the angle of rotation is negative, the beam flexes according to the second operating regime.

According to one embodiment, the electrostatic actuator is driven at a modulation frequency that differs from the frequency of movement of the beam. The signal resulting from each strain gauge can be demodulated based on the modulation frequency, in such a manner as to extract a component representative of the flexion of the beam induced by the actuator. This makes it possible to determine the variation in the angle of rotation resulting from activation of the actuator; in this way, the operating regime of the beam is identified.

According to another possibility, the microsystem comprises a contact detector configured to detect contact between the beam and the first-rank stop 20₁. This detector may, in a non-limiting manner, be a mechanical or electrical or electrostatic or capacitive or magnetic detector. The type of detector depends on the properties of the material forming the beam, particularly the conductivity thereof. The processing unit 19 may determine the amplitude of flexion of the beam or the load applied to the beam and/or the angle of rotation, based on the contact detected between the beam and the first-rank stop.

If the operating regime cannot be determined, the microsystem remains useable in the first operating regime, with the advantage of avoiding any risk of damage to the strain gauge in the event of overpressure.

In the embodiment described with reference to FIGS. 3A to 3F, the flexural loading being applied to the beam results from a pressure differential on either side of the beam. This load can be assimilated to a linear force density considered uniform along the entire length of the beam. The distance d₁ between the first stop 20₁ and the base 13 is preferably less than 58%, or between 10% and 75%, or between 10% and 60% of the total length l of the beam 10, between the base 13 and the end 14. The offset e₁ between the first stop 20₁ and the central axis A is determined according to the maximum stress level that can be properly applied to the strain gauges. The minimum offset eₘᵢₙ that can be obtained with the manufacturing or assembly method of the device limits the minimum distance d₁ that can be adopted: whereas θₘₐₓ is the maximum allowable angle of rotation, for a first stop located close to the base, the following expression can be written under a small-angle approximation: d₁θₘₐₓ=e₁≥eₘᵢₙ which necessarily implies that d₁≥eₘᵢₙ/Θₘₐₓ.

The minimum offset eₘᵢₙ corresponds, for example, to the thickness of the substrate from which the device is fabricated, divided by 20. θₘₐₓ may be in the order of 1° to 2°.

With regard to one or more stops of rank n greater than 1, their respective positions depend on the deformation profile of the beam. The adopted offsets eₙ preferably ensure that the base 13 returns to the zero-rotation configuration, i.e. a zero angle of rotation, when the beam comes into contact with a higher-rank stop.

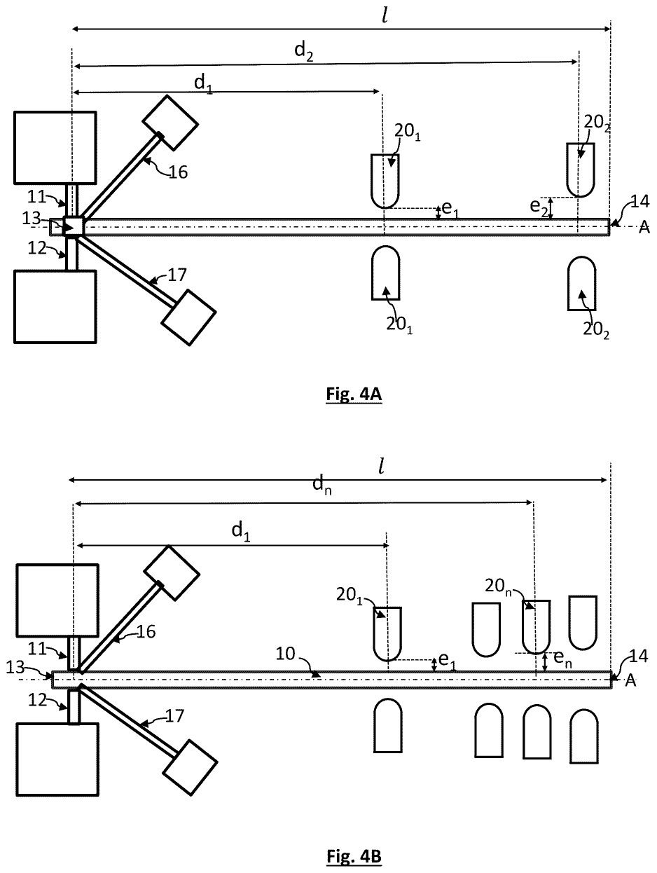

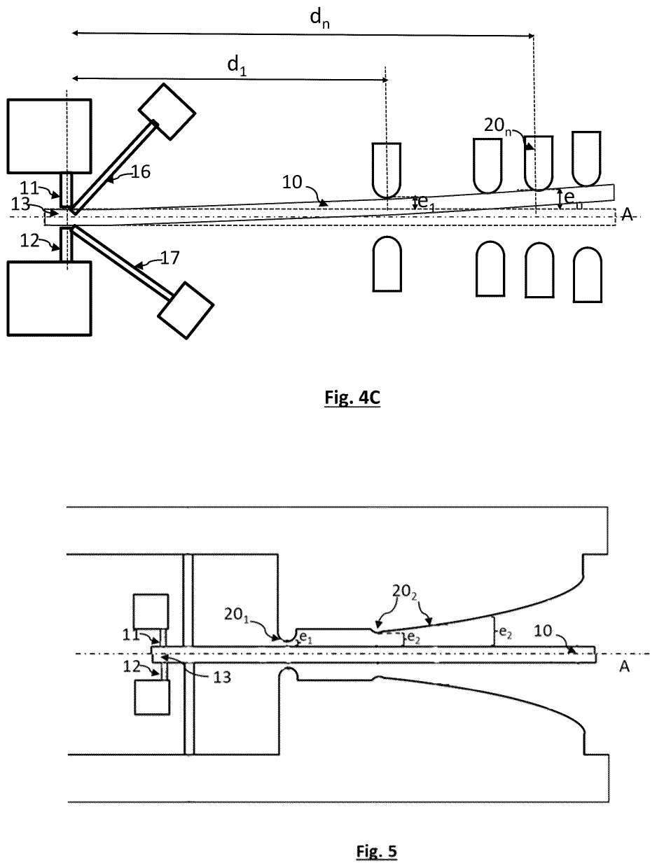

In the embodiment described in connection with FIGS. 3A and 3F, a number N of stops equal to 3 is used. However, N may be equal to 2, as shown in FIG. 4A, or greater than 3, as shown in FIGS. 4B and 4C. When a number of stops equal to or greater than 3 is used, it may be advantageous for the positions of the stops beyond rank 1 to be determined according to the deformation profile of the beam. This enables stops with a rank higher than 2 to come into contact with the beam simultaneously. This is considered advantageous.

However, it is also possible for stops with a rank higher than 1 to come into contact with the beam successively as the load increases, with a stop of rank n coming into contact at a load value lower than the one at which the beam comes into contact with a stop of rank n+1.

A high number of stop ranks introduces a damping effect due to the compression of a gas film extending between each stop and the beam prior to contact. The addition of damping is not recommended for microphone-type applications, in which the thermomechanical noise associated with viscous damping adversely affects the signal-to-noise ratio. However, the addition of damping may be suitable for applications of the microsystem in devices such as accelerometers.

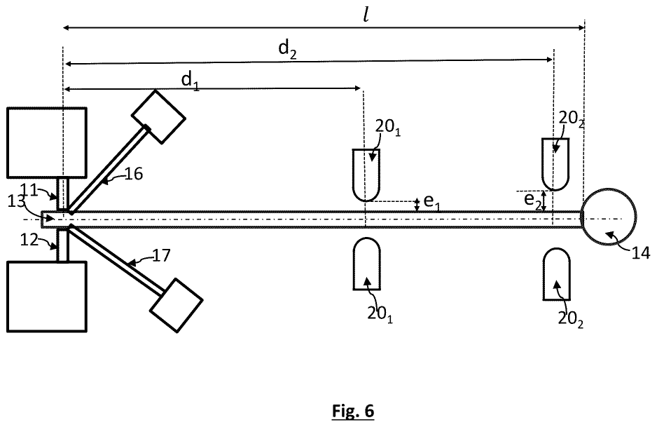

FIG. 5 shows an embodiment in which the second-rank stop extends over a substantial length facing the beam, matching the deformation profile of the beam. The second offset, which corresponds to the distance between the second-rank stop and the equilibrium position, increases depending on the distance from the base. This spatial variation of the second offset corresponds to the deformation profile of the beam. In this configuration, once the beam has made contact with the first-rank stop, it bears against the first-rank stop and continues to deform while approaching the second-rank stop. This results in a reduction in the angle of rotation, as explained in relation to the previous embodiments. Owing to the fact that the shape of the second-rank stop matches the deformation profile of the beam, the beam comes to bear simultaneously against the surface of the stop. The size of the stop along the length of the beam may cause compression of the gas film extending between the beam and the second-rank stop; this may lead to a damping effect, as described in connection with FIGS. 4B and 4C.

The invention both ensures the reliable operation of a microsystem and enables an increase in the measurement dynamic range.

Although described in connection with the manufacture of a microphone, the invention can be applied to other types of devices, for example a gyroscope or an accelerometer. In the previously described embodiments, the linear force density exerted on the beam, which induces flexion, can be considered uniform. This is also the case when the device is an accelerometer in which the beam is used as the proof mass.

According to another possibility described with reference to FIG. 6, the end 14 of the beam forms a movable mass. The beam 10 acts as a lever arm allowing conversion of the force applied by the moving mass onto the beam into a rotational moment on the base. The rotation of the base is therefore linked to the movement of the movable mass at the end of the beam. The end 14 may be connected to a restoring element that applies a restoring force to bring the beam back to its equilibrium position.

1. A microsystem, comprising:
a beam extending from a base to an end, the beam being configured to be flexurally movable within a flexion plane under the effect of a mechanical load, starting from an equilibrium position, the beam extending along a central axis when it occupies the equilibrium position, the beam being configured to cause the base to rotate about an axis of rotation, under the effect of a flexion, by an rotation angle within the flexion plane, the rotation angle being defined relative to the central axis;
at least one strain gauge configured to deform when the rotation angle increases, the strain gauge being configured to generate a detection signal dependent on the rotation angle;
wherein the microsystem comprises a first-rank stop and a second-rank stop, each stop being configured to come into contact with the beam;
wherein:
the first stop is arranged, along the central axis, between the second-rank stop and the base;
the first-rank stop extends at a first offset from the equilibrium position, the first-rank stop being configured to come into contact with the beam when the end is displaced from the equilibrium position beyond a first displacement;
the second-rank stop extends at a second offset, greater than the first offset, from the central axis, relative to the equilibrium position, the second-rank stop being configured to come in contact with the beam when the end is displaced from the equilibrium position by a second displacement, greater than the first displacement;
so that:
when the end is displaced from the equilibrium position to the first
displacement, the rotation angle increases;
when the end is displaced from the first displacement to the second displacement, the rotation angle decreases under the effect of a deflection of the beam as the beam bears against the first-rank stop.

2. The microsystem according to claim 1, comprising multiple n rank stops, where n i an integer greater than or equal to 2, wherein each n rank stop is arranged:
along the central axis, at a distance from the base that increases as the rank of
the stop increases;
perpendicular to the central axis, at an offset from the equilibrium position that increases as the rank of the stop increases;
wherein the n rank stop extends at an n-th offset, greater than the (n−1)th offset,
from the equilibrium position, the n rank stop being configured to be in contact with the beam when the end is displaced from the equilibrium position by an n-th displacement, greater than the (n−1)th displacement.

3. The microsystem according to claim 2, wherein the stops of rank greater than or equal to 2 are positioned to come into contact with the beam simultaneously, the stops being positioned according to a deflection profile of the beam.

4. The microsystem according to claim 2, wherein the stops of rank greater than or equal to 2 are positioned to come into contact with the beam successively, the stops being positioned according to a deflection profile of the beam.

5. The microsystem according to claim 1, wherein a stop of rank greater than or equal to 2 is configured in so that the offset between said stop and the equilibrium position increases as a function of the distance between the stop and the base, wherein the shape of the stop corresponds to a deflection profile of the beam.

6. The microsystem according to claim 1, in which the strain gauge is a piezoresistive or piezoelectric gauge.

7. The microsystem according to claim 1, wherein:
the beam extends over a length between the base and the end;
the first distance ranges between 0.2 and 0.6 times the length.

8. The microsystem according to claim 1, comprising a processing unit configured to:
receive the detection signal;
estimate the angle of rotation of the beam based on the detection signal.

9. The microsystem according to claim 8, wherein the processing unit is configured to calculate a amplitude of flexion of the beam as a function of the rotation angle.

10. The microsystem according to claim 8, in which:
the beam is coupled to an actuator configured to induce flexion of the beam;
the processing unit is configured to extract a variation of the detection signal in response to the flexion induced by the actuator and to determine the angle of rotation and/or the amplitude of flexion of the beam based on said variation of the detection signal.

11. The microsystem according to claim 8, comprising a contact detector for detecting contact between the beam and the first-rank stop.

12. The microsystem according to claim 11, in which the processing unit is configured to determine the angle of rotation and/or the amplitude of flexion of the beam based on contact between the beam and the first-rank stop.

13. The microsystem according to claim 1, comprising a chamber, the microsystem being such that the beam forms a diaphragm delimiting the chamber, the beam being configured to undergo flexion in response to a pressure differential on either side of the beam.

14. The microsystem according to claim 1, in which the end of the beam forms a mass, in such a manner that the beam follows a flexural movement in response to a displacement of the mass, in such a manner that the displacement of the mass causes the base to rotate.

15. A Measuring device, comprising the microsystem according to claim 1, the measurement device being configured to measure an amplitude of flexion of the beam.
